(19) United States
(12) Patent Application Publication
(10) Pub. No.: US 2011/0139218 A1
(43) Pub. Date: Jun. 16, 2011

(54) ENCAPSULANT MATERIAL FOR PHOTOVOLTAIC MODULES

(75) Inventors: Jack I. Hanoka, Brookline, MA (US); Robert J. Statz, Kennett Square, PA (US)

(73) Assignee: 7Solar Technologies, Inc., Woburn, MA (US)

(21) Appl. No.: 12/896,279

(22) Filed: Oct. 1, 2010

Related U.S. Application Data
(60) Provisional application No. 61/247,685, filed on Oct. 1, 2009.

(51) Int. Cl. H01L 31/052; H01L 31/048

(52) U.S. Cl. 136/246; 427/74

(57) ABSTRACT

A photovoltaic module includes a solar cell layer having a front side for receiving light and an opposite back side, and an encapsulant layer on at least the front side of the solar cell layer. The encapsulant layer comprises a lithium ionomer for increasing the conversion efficiency of the photovoltaic module.

### CROSS REFERENCE TO RELATED APPLICATION

This application claims priority from U.S. Provisional Patent Application Ser. No. 61/247,685, filed on Oct. 1, 2009, entitled Novel Encapsulant Material for Photovoltaic Modules, which is hereby incorporated by reference.

### BACKGROUND

The present application generally relates to photovoltaic modules and, more particularly, to photovoltaic modules with increased conversion efficiencies.

In order to make electricity generated from sunlight via photovoltaic (i.e., solar cell) modules equivalent in cost to electricity generated from conventional sources and to increase its usage, a significant reduction in the cost of solar cell modules is needed. A direct way to lower the cost of photovoltaic modules is to increase the conversion efficiency of the modules without increasing their manufacturing cost.

The structure of a photovoltaic module can vary according to type of solar cell that is used. There are, generally speaking, three types. One is based on crystalline silicon solar cells, and these now dominate the industry. Another is based on thin film solar cells that can be made from amorphous silicon (αSi), cadmium telluride (CdTe), and copper indium gallium diselenide (CIGS). A third category includes cells that are made from polymers, so-called dye sensitized cells, and cells made from nano particles. All of these modules utilize a transparent polymer that is termed the encapsulant or pottant. For crystalline silicon solar cells, the typical module structure comprises: a superstrate or front glass, an encapsulant layer, the solar cells, another encapsulant layer, and then a backskin. For thin film solar cell modules, in some instances, the front glass is replaced with Tefzel® (a modified ETFE (ethylene-tetrafluoroethylene) fluoropolymer available from DuPont). In some other cases, the encapsulant layer is behind the active solar cell layer, which is deposited on the inside surface of the front glass.

Disclosed herein are novel encapsulant materials that increase the conversion efficiency of photovoltaic modules for those applications where the encapsulant layer is above the active solar cells.

Ethylene Vinyl Acetate (EVA) is the predominantly utilized encapsulant for photovoltaic modules. Other encapsulant materials that are under consideration include poly vinyl butyral (PVB), silicone, and ionomer. PVB is used as the material sandwiched between two pieces of glass for automobile windshields. It requires careful environmental control as it is very moisture sensitive. Silicone is more expensive than virtually any other possible encapsulant, but offers the advantage of better U.V. light stability than almost any other polymer. An ionomer with a Zn cation is now available commercially for PV applications.

For long term performance considerations as well as moisture ingress issues, EVA has some very significant drawbacks. EVA is a copolymer of vinyl acetate and polyethylene. The high level of vinyl acetate (33%) in the copolymer reduces the thermal stability of the material. There will be significant thermal breakdown starting at 220° C. Also, in long term exposure at lower temperatures similar to that in direct sunlight, there is definite evidence of acetic acid, which is a byproduct of the thermal degradation process. This acid can eventually result in corrosion of the metal contacts. It has been discovered through experimentation that when small experimental sized modules laminated with EVA are placed in an environmental chamber at a temperature of 125° C. in the dark, yellowing occurs after several weeks of exposure. Yellowing is an indication of degradation. Also, the high level of the vinyl acetate in EVA lowers the overall chemical resistance and solvent resistance of the encapsulant. This high vinyl acetate structure is more amorphous and hence the rate of oxygen permeation and water vapor penetration is increased. The presence of oxygen in combination with the acetic acid byproduct is thought to be one reason the system develops yellowness with aging. The high penetration of water vapor is a particular problem for some kinds of thin film modules, particularly CdTe and CIGS.

To achieve the desired level of clarity for EVA, at least 33% vinyl acetate is used. This destroys the polymer crystallinity and lowers the melting point to such a low level that a special blend of thermally active organic peroxide is needed so that in the final cure of the encapsulation system during the lamination process, it will cross-link the polymer. In some prior work, a study of the long term stability of EVA vs. an encapsulant material that is chemically similar to ionomer was done. Samples were laminated under window glass and subjected to 5 to 8× mirror enhanced sunlight in Arizona. The degree of degradation was measured every month by measuring the yellowness index change, a common measure used for determining polymer degradation. The results are shown in FIG. 1.

The mirror enhancement is a factor of 5 to 8 greater in overall light exposure than ordinary sunlight. While simple linear extrapolations need to be done with some caveats, such an extrapolation in this case would mean that 5×55 months or 8×55 months or anywhere from about 23 to 37 years with no significant indication of yellowing compared to EVA. Modules are known to lose up to 1% power per year, usually beginning after some time, say 5 to 10 years. Part of this drop in power is likely to due to some degree of yellowing of the EVA with a consequent loss in light transmission. Also, as discussed above, as the EVA degrades, it will produce some acetic acid. This acid can eventually result in corrosion of the metal contacts. One manufacturer of modules has stated that corrosion of the contacts was responsible for some 45% of module failures in the field for their modules.

### BRIEF SUMMARY OF EMBODIMENTS OF THE INVENTION

A photovoltaic module in accordance with one or more embodiments includes a solar cell layer having a front side for receiving light and an opposite back side, and an encapsulant layer on at least the front side of the solar cell layer. The encapsulant layer comprises a lithium ionomer for increasing the conversion efficiency of the photovoltaic module.

In accordance with one or more embodiments, a method is provided of forming an encapsulant layer for covering at least the front side of a solar cell layer in a photovoltaic module. The method includes the steps of providing an acid copolymer of polyethylene, and neutralizing the acid copolymer with lithium cations to form a lithium ionomer.

Various embodiments of the invention are provided in the following detailed description. As will be realized, the invention is capable of other and different embodiments, and its several details may be capable of modifications in various respects, all without departing from the invention. Accordingly, the drawings and description are to be regarded as illustrative in nature and not in a restrictive or limiting sense, with the scope of the application being indicated in the claims.

### BRIEF DESCRIPTION OF THE DRAWINGS

FIG. 1 is a graph illustrating the yellowness change under enhanced sunlight for two different encapsulant materials.

FIG. 2 is a simplified cross-sectional view of an exemplary photovoltaic module in accordance with one or more embodiments.

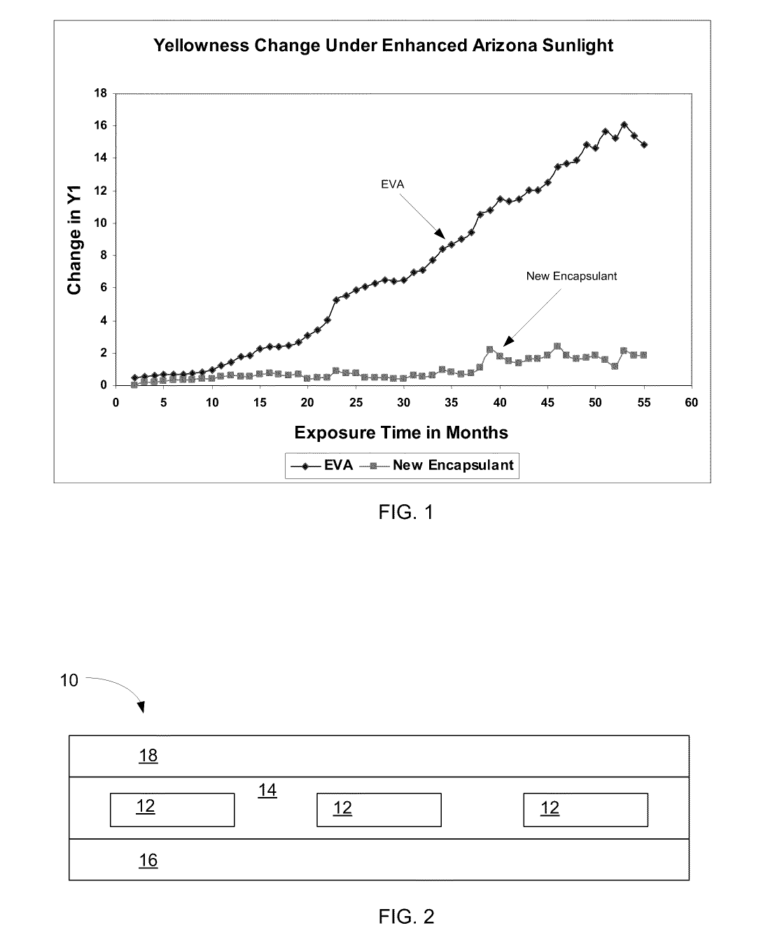

### DETAILED DESCRIPTION

FIG. 2 is a simplified cross-sectional view of one example of a photovoltaic module 10 in accordance with one or more embodiments, in which the disclosed encapsulant materials may be used. The photovoltaic module 10 includes one or more photovoltaic or solar cells 12 arranged in a layer. Examples of suitable materials for the photovoltaic cells 12 include, but are not limited to, crystalline silicon, thin film solar cells (e.g., amorphous silicon, cadmium telluride, and copper indium gallium diselenide), and solar cells made from polymers, so-called dye sensitized cells, and nano particles. The front sides of the solar cells 12 (i.e., the side exposed to light) are covered by an encapsulant layer 14. A backskin layer 16 can be provided on the back side of the photovoltaic cells 12. In the example shown in FIG. 2, the encapsulant layer 14 wraps completely around the photovoltaic cells 12, sealing the photovoltaic material. In other examples the encapsulant layer 14 covers only the front side of the solar cells 12. A superstrate or front glass 18 is disposed on the front side of the encapsulant layer 14 to seal and protect the solar cells 12 and other components from impact and environmental degradation.

In accordance with various embodiments, novel varieties of a different copolymer of polyethylene, namely ionomers, are provided as significantly improved alternatives to EVA encapsulants in solar cells. Ionomers are polymers of ethylene//meth/acrylate esters//meth/acrylic acid compositions. In accordance with one or more embodiments, the meth/acrylate is a C1-C9 ester of acrylic or methacrylic acid, the ester is present from 0 to 30% by weight, the acid is present from 4 to 30% by weight, and the acid is neutralized from 5 to 90% with lithium cations. Alternatively, the acids can be neutralized with selected rare earth cations or mixtures of rare earth cations that cause shifts in the wavelength of ambient light to wavelengths useful for generating electricity in photovoltaic solar cells. The ionomer encapsulant can be selected to be used with materials other than silicon.

In accordance with various embodiments, changes in the ionomer structure are disclosed that result in an increase in visible light reaching the solar cells under this encapsulant. The changes in the ionomer structure can be achieved as follows: In one or more embodiments, it is the use of lithium as the cation and with the lithium ionomer made in a particular chemical fashion that provides this lithium ionomer with higher transparency than that of any other ionomer and higher than that of EVA. It is believed that this higher transparency is due to the fact that lithium is a smaller ion than some of the other possible ions used, such as sodium, zinc, and magnesium. The measurement of haze is used as measure of transmission of transparent polymer sheets. The haze value of the present commercially available zinc ionomer is 3. The lithium ionomer, when made in a particular way chemically, has haze values of 1.5. The preferred method for producing the lithium ionomer is by neutralizing the acid copolymer with a solution of lithium hydroxide monohydrate. Blends with acid copolymers containing less than 15% by weight comonomers are preferably avoided as these polymers lead to increased haze levels and lower transparency.

In accordance with one or more further embodiments, rare earth ions are added to the lithium ionomer. Because of their unique structure, ionomers can also form ionic bonds with rare earth ions. Many of these rare earth ions, when very close to each other as they are uniquely so in ionomers, can do up conversion and down conversion of incoming photons. Down conversion means that for an initial high energy photon (whereby normally the excess energy above that required to form a hole-electron pair is just used to heat up the solar cell) now can be employed to form two lower energy photons each of which can be used to create hole-electron pairs. Up conversion is a process in which photons that normally do not posses sufficient energy to generate hole-electron pairs are combined with similar photons such that the new combined energy is adequate to form hole-electron pairs.

In accordance with one or more embodiments, the flex modulus of the lithium ionomer is changed. There is a zinc ionomer that is used commercially for photovoltaic modules, including crystalline silicon modules. The Li ionomer is known to be stiffer (i.e., having a higher flex modulus) than Zn ionomers. The flex modulus for Li ionomer is on the order of 400 mPa whereas the Zn ionomer is about 250 mPa, so the Li ionomer is almost 40% higher. For crystalline silicon modules, excessive encapsulant stiffness could lead to cell breakage. This issue can be mitigated by modifying the Li ionomer through the addition of a small amount of butyl acrylate and to form what is termed a terpolymer. Butyl acrylate is known to act as an additive that can reduce the flex modulus. In any case, this may not be an issue for thin film modules.

In accordance with one or more further embodiments, nanoparticles of a higher refractive index material such as aluminum oxide (Al₂O₃) are added to the ionomer in order to increase the refractive index of the ionomer. Al₂O₃ has an index of refraction of approximately 1.75 and when added to the ionomer increase the refractive index of the ionomer. In this way, an increase of approximately two to three percent of the total possible light that could be absorbed by a crystalline silicon solar cell can be realized (reference below). Furthermore, it has been pointed out that higher relative increases in sunlight absorption are possible with a higher refractive index for the encapsulant layer in the cases for low angle of incidence close to sun rise and sun set. (Solar Electric Power Generation—Photovoltaic Energy Systems, by Stefan C. W. Krauter, Springer-Verlag Berlin Heidelberg, 2006). Such an effect can be viewed as a way of simulating tracking (at least in a small way) for what is a non-tracking flat plate photovoltaic module.

It is to be understood that although the invention has been described above in terms of particular embodiments, the foregoing embodiments are provided as illustrative only, and do not limit or define the scope of the invention. Various other embodiments, including but not limited to the following, are also within the scope of the claims. For example, elements and components described herein may be further divided into additional components or joined together to form fewer components for performing the same functions.

Having described preferred embodiments of the present invention, it should be apparent that modifications can be made without departing from the spirit and scope of the invention.

What is claimed is:

1. A photovoltaic module comprising:
a solar cell layer having a front side for receiving light and an opposite back side; and
an encapsulant layer on at least the front side of the solar cell layer, said encapsulant layer comprising a lithium ionomer for increasing the conversion efficiency of the photovoltaic module.

2. The photovoltaic module of claim 1 wherein the lithium ionomer has a haze value of about 1.5.

3. The photovoltaic module of claim 1 wherein the lithium ionomer is formed by neutralizing an acid copolymer of polyethylene with a solution of lithium hydroxide monohydrate.

4. The photovoltaic module of claim 1 wherein said lithium ionomer comprises a C1-C9 ester of acrylic or methacrylic acid, wherein the ester is present from 0 to 30% by weight, the acid is present from 4 to 30% by weight, and the acid is neutralized from 5 to 90% with lithium cations.

5. The photovoltaic module of claim 1 wherein the lithium ionomer further comprises rare earth ions.

6. The photovoltaic module of claim 1 wherein the lithium ionomer further comprises rare earth ions neutralizing an acid copolymer of polyethylene to cause shifts in the wavelength of ambient light to wavelengths useful for generating electricity in photovoltaic solar cells.

7. The photovoltaic module of claim 1 wherein the lithium ionomer further comprises butyl acrylate to reduce the flex modulus thereof.

8. The photovoltaic module of claim 1 wherein the lithium ionomer further comprises nanoparticles of a higher refractive index material to increase the refractive index of the ionomer.

9. The photovoltaic module of claim 8 wherein the refractive index material comprises aluminum oxide.

10. A method of forming an encapsulant layer for covering at least the front side of a solar cell layer in a photovoltaic module comprising:
providing an acid copolymer of polyethylene; and
neutralizing the acid copolymer with lithium cations to form a lithium ionomer.

11. The method of claim 10 wherein the lithium ionomer has a haze value of about 1.5.

12. The method of claim 10 wherein neutralizing the acid copolymer comprises neutralizing the acid copolymer with a solution of lithium hydroxide monohydrate.

13. The method of claim 10 wherein said lithium ionomer comprises a C1-C9 ester of acrylic or methacrylic acid, wherein the ester is present from 0 to 30% by weight, the acid is present from 4 to 30% by weight, and the acid is neutralized from 5 to 90% with lithium cations.

14. The method of claim 10 further comprising adding rare earth ions to the acid copolymer.

15. The method of claim 10 further comprising neutralizing the acid copolymer with selected rare earth cations or mixtures thereof that cause shifts in the wavelength of ambient light to wavelengths useful for generating electricity in photovoltaic solar cells.

16. The method of claim 10 further comprising adding butyl acrylate to the lithium ionomer to reduce the flex modulus thereof.

17. The method of claim 10 further comprising adding nanoparticles of a higher refractive index material to the lithium ionomer to increase the refractive index thereof.

18. The method of claim 17 wherein the refractive index material comprises aluminum oxide.
